(19) United States
(12) Patent Application Publication
(10) Pub. No.: US 2026/0213769 A1
(43) Pub. Date: Jul. 23, 2026

(54) COMPRESSION DEVICE AND MEMORY SYSTEM

(71) Applicant: Kioxia Corporation, Tokyo (JP)

(72) Inventor: Kohei OIKAWA, Yokohama Kanagawa (JP)

(73) Assignee: Kioxia Corporation, Tokyo (JP)

(21) Appl. No.: 19/300,769

(22) Filed: Aug. 15, 2025

(30) Foreign Application Priority Data
Jan. 22, 2025 (JP) 2025-009014

(51) Int. Cl. H03M 7/30

(52) U.S. Cl. CPC H03M 7/3088; H03M 7/6005; H03M 7/6011

(57) ABSTRACT

According to one embodiment, a compression device includes a dictionary-based compression circuit and an input control circuit. The dictionary-based compression circuit is configured to perform dictionary-based encoding on first data a plurality of times. The input control circuit is configured to output the first data from a specified start position to a match candidate search circuit as first input data, and output the first data from a head position to a dictionary buffer as second input data having the same length as the first input data. The dictionary-based compression circuit is configured to compare the size of current compressed data with the size of past compressed data, and output compressed data having a smaller size.

### CROSS-REFERENCE TO RELATED APPLICATIONS

This application is based upon and claims the benefit of priority from Japanese Patent Application No. 2025-009014, filed Jan. 22, 2025, the entire contents of which are incorporated herein by reference.

### FIELD

Embodiments described herein relate generally to a compression device and a memory system.

### BACKGROUND

Typically, a compression device having a dictionary-based compression circuit buffers data that has been input in the past in a dictionary buffer, searches for data that matches input data among past data in the dictionary buffer, and when matching data is stored in the dictionary buffer, replaces the input data with a match distance, which is the address of the dictionary buffer, and a match length, which indicates the length of the matching data, and outputs the same as a dictionary-based compression result, thereby performing compression.

A method of improving the compression ratio of the dictionary-based compression circuit is to increase the size of the dictionary buffer (dictionary buffer size). This is because the larger the dictionary buffer size, the wider the search range for past data can be. However, increasing the dictionary buffer size results in increase in the circuit scale of the dictionary-based compression circuit.

### BRIEF DESCRIPTION OF THE DRAWINGS

FIG. 1 is a diagram showing an example of the configuration of an information processing system including a compression device according to a first embodiment.

FIG. 2 is a diagram showing an example of dictionary-based compression in the compression device according to the first embodiment.

FIG. 3 is a block diagram showing an example of the configuration of the compression device according to the first embodiment.

FIG. 4 is a diagram showing an example of compression processing performed by the compression device according to the first embodiment.

FIG. 5 is a flowchart showing an example of a procedure of compression processing performed by the compression device according to the first embodiment.

FIG. 6 is a flowchart showing an example of the procedure of compression processing performed by the compression device according to the first embodiment.

FIG. 7 is a block diagram showing an example of the configuration of a compression device according to a second embodiment.

FIG. 8 is a block diagram showing an example of the configuration of a compression device according to a third embodiment.

FIG. 9 is a block diagram showing an example of the configuration of a compression device according to the third embodiment.

FIG. 10 is a block diagram showing an example of the configuration of the compression device according to the third embodiment.

### DETAILED DESCRIPTION

In general, according to one embodiment, a compression device compresses input first data. The compression device includes a dictionary-based compression circuit and an input control circuit. The dictionary-based compression circuit includes a dictionary buffer, a match candidate search circuit, and a match selection circuit and is configured to perform dictionary-based encoding on the first data a plurality of times. The input control circuit is configured to output input data based on the first data to the dictionary-based compression circuit. The input control circuit is configured to output the first data from a specified start position to the match candidate search circuit as first input data, and output the first data from a head position to the dictionary buffer as second input data having the same length as the first input data. The dictionary buffer is configured to store, as dictionary data, the dictionary buffer size of data among the second input data sequentially input from the input control circuit. The match candidate search circuit is configured to acquire the dictionary data that at least partially matches the first input data sequentially input from the input control circuit, and generate compressed data through current dictionary-based encoding. When there is compressed data corresponding to the first data generated in the past by the match candidate search circuit, the match selection circuit is configured to compare the size of the compressed data generated through the current dictionary-based encoding with the size of compressed data generated in the past and corresponding to the specified start position, and output compressed data having a smaller size. When there is no compressed data corresponding to the first data generated in the past by the match candidate search circuit, the match selection circuit is configured to output the compressed data generated through the current dictionary-based encoding.

Hereinafter, embodiments will be described with reference to the drawings.

### First Embodiment

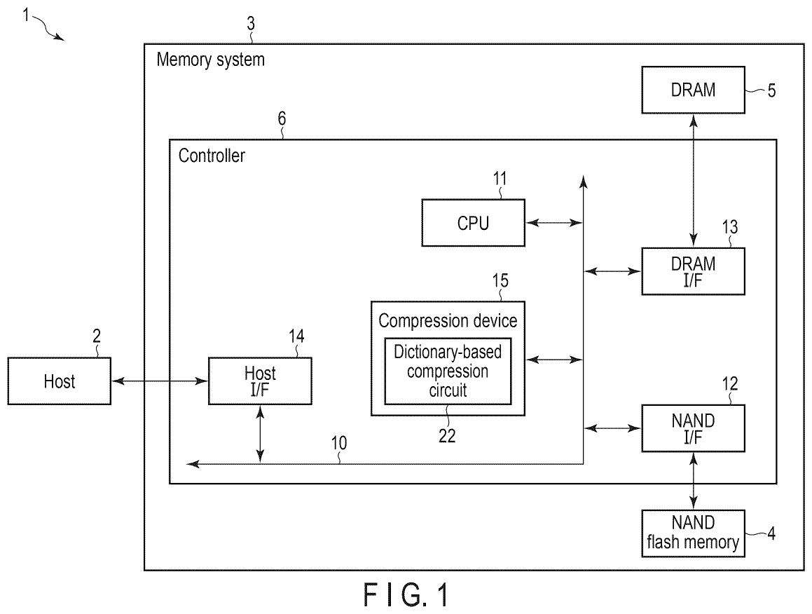

FIG. 1 shows an example of the configuration of an information processing system including a compression device according to a first embodiment. The information processing system 1 includes a host device 2 and a memory system 3.

The host device 2 is an information processing device that stores data in the memory system 3. The host device 2 is, for example, a storage server or a personal computer that stores a large amount of diverse data in the memory system 3. Hereinafter, the host device 2 will be referred to as a host 2.

The memory system 3 is a semiconductor storage device configured to write data to a non-volatile memory and read data from the non-volatile memory. The non-volatile memory is, for example, a NAND flash memory 4. The memory system 3 is realized as, for example, a solid state drive (SSD). Hereinafter, an example in which the memory system 3 is realized as an SSD will be described, but the memory system 3 may also be realized as a hard disk drive (HDD).

The memory system 3 can be used as a storage for the host 2. The memory system 3 may be built into the host 2 or may be connected to the host 2 via a cable or a network.

An interface for connecting the host 2 and the memory system 3 complies with standards such as SCSI, Serial Attached SCSI (SAS), AT Attachment (ATA), Serial ATA (SATA), PCI Express (PCIe) (registered trademark), Ethernet (registered trademark), Fibre channel, NVM Express (NVMe) (registered trademark), and the like.

The memory system 3 includes, for example, a NAND flash memory 4, a dynamic random access memory (DRAM) 5, and a controller 6.

The NAND flash memory 4 includes one or more memory chips. Each memory chip includes a plurality of blocks. A block functions as the smallest unit of a data erase operation. A block may be called an “erase block” or a “physical block”. Each of the blocks includes a plurality of pages. Each of the pages includes a plurality of memory cells connected to a single word line. A page functions as a unit of a data write operation and a data read operation. Note that a word line may also function as a unit of the data write operation and the data read operation.

There is an upper limit to the number of program/erase cycles (P/E cycle number) for each block, which is called a maximum P/E cycle number. One P/E cycle for a certain block includes an erase operation for putting all memory cells in the block into an erased state, and a write operation for writing data to each page of the block.

The DRAM 5 is a volatile memory. The memory area of the DRAM 5 is allocated, for example, as a storage area for firmware (FW), a cache area for a logical-physical address conversion table, and a buffer area for user data.

The controller 6 is a memory controller that controls the NAND flash memory 4 and the DRAM 5. The controller 6 is realized, for example, by controller circuitry such as a system-on-a-chip (SoC). The controller 6 may have a built-in static random access memory (SRAM) or DRAM. In this case, the DRAM 5 external to the controller 6 may not be provided.

The controller 6 functions as, for example, a flash translation layer (FTL) configured to perform data management and block management of the NAND flash memory 4. The data management performed by the FTL includes (1) management of mapping information indicating the correspondence between each logical address and each physical address of the NAND flash memory 4, and (2) processing for concealing the difference between a page-based data read operation/data write operation and a block-based data erase operation. The block management includes management of bad blocks, wear leveling, and garbage collection.

A logical address is used by the host 2 to address a storage area of the memory system 3. A logical address is, for example, a logical block address (LBA).

The management of mapping between each logical address and each physical address is performed, for example, by using a logical-physical address conversion table. The controller 6 uses the logical-physical address conversion table to manage mapping between each logical address and each physical address in a specific management size unit. A physical address corresponding to a certain logical address indicates a physical storage location in the NAND flash memory 4 where user data of the logical address has been written. The logical-physical address conversion table may be loaded from the NAND flash memory 4 to the DRAM 5 when the memory system 3 is started up.

Data can be written to one page only once per P/E cycle. Therefore, the controller 6 writes updated user data corresponding to a certain logical address to a different physical storage location, rather than to the physical storage location where the previous user data corresponding to this logical address is stored. The controller 6 then invalidates the previous user data by updating the logical-physical address conversion table to associate this logical address with this different physical storage location.

The controller 6 includes, for example, a CPU 11, a NAND interface (NAND I/F) 12, a DRAM interface (DRAM I/F) 13, a host interface (host I/F) 14, and a compression device 15. The CPU 11, the NAND I/F 12, the DRAM I/F 13, the host I/F 14, and the compression device 15 are connected, for example, via a bus 10.

The CPU 11 is a processor configured to control the NAND I/F 12, the DRAM I/F 13, the host I/F 14, and the compression device 15. The CPU 11 performs various types of processing by executing FW loaded from the NAND flash memory 4 to the DRAM 5. The FW is a control program including a group of instructions for causing the CPU 11 to perform various types of processing. The CPU 11 performs command processing for processing various commands from the host 2 in addition to the above-described FTL processing. The operation of the CPU 11 is controlled by the FW executed by the CPU 11. Note that some or all of FTL processing and command processing may be executed by dedicated hardware in the controller 6.

The NAND I/F 12 electrically connects the controller 6 and the NAND flash memory 4. The NAND I/F 12 supports interface standards such as Toggle DDR and Open NAND Flash Interface (ONFI).

The NAND I/F 12 functions as NAND control circuitry configured to control the NAND flash memory 4. The NAND I/F 12 may be connected to a plurality of memory chips within the NAND flash memory 4 via a plurality of channels (Ch). By driving the memory chips in parallel, it is possible to broaden the bandwidth of access to the entire NAND flash memory 4.

The DRAM I/F 13 functions as DRAM control circuitry configured to control access to the DRAM 5.

The host I/F 14 is circuitry that functions as an interface for communication between the memory system 3 and the host 2. The host I/F 14 includes circuitry that receives various commands from the host 2, such as input/output (I/O) commands and various control commands. The I/O commands may include a write command and a read command. The control commands may include an unmap command (trim command) and a format command. The host I/F 14 includes circuitry that transmits a response or data corresponding to a command to the host 2.

The compression device 15 is an encoder that compresses data to be written to the NAND flash memory 4 by encoding the data. For example, the CPU 11 inputs write data received in response to reception of a write command received from the host 2 as plain data to the compression device 15. The compression device 15 encodes the plain data input from the CPU 11. The compression device 15 includes, for example, a dictionary-based compression circuit 22 in order to compress data.

The dictionary-based compression circuit 22 is a data compression circuit that performs dictionary-based encoding on input data.

Dictionary-based encoding is a coding method of converting data to be compressed into a match distance and a match length by using a dictionary buffer that holds data that has been input in the past. Dictionary-based encoding is also called dictionary-based compression. In dictionary-based compression, the dictionary buffer is searched to obtain past data that at least partially matches data to be compressed, and a match distance and a match length are obtained. The match distance is the distance from the position at which the data to be compressed is stored to the position at which the obtained past data is stored in the dictionary buffer. The match length is the length of the portion that matches between the obtained past data and the data to be compressed. The data to be compressed can be compressed by converting the data to be compressed into a match distance and a match length. Note that when past data that at least partially matches the data to be compressed is not stored in the dictionary buffer, the dictionary-based compression circuit 22 outputs the data to be compressed intact.

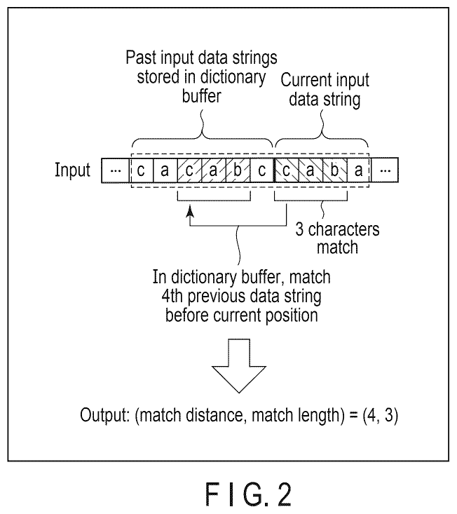

FIG. 2 is a diagram showing an example of dictionary-based compression. In the example shown in FIG. 2, a data string “ . . . cacabc” that has been input in the past is stored in the dictionary buffer. The current input data string is “caba”.

In this case, the first two characters of the current input data string “caba” match a data string “ca” stored in the dictionary buffer six characters before the position at which the current input data string “caba” is stored. Further, the first three characters of the current input data string “caba” match a data string “cab” stored in the dictionary buffer four characters before the position at which the current input data string “caba” is stored.

In dictionary-based compression, the current input data string “caba” is converted into a match distance and a match length that relatively refer to a longer matching data string in the dictionary buffer.

Therefore, the current input data string “caba” is converted into a match distance “4” and a match length “3” that relatively refer to the data string “cab” in the dictionary buffer. The match distance “4” indicates the relative distance from the position at which the current input data string “caba” is stored to the position at which the data string “cab” is stored in the dictionary buffer. The match length “3” indicates the length of the portion that matches between the current input data string “caba” and the data string “cab”. Therefore, when dictionary-based compression has been performed on the current input data string “caba”, the dictionary-based compression circuit 22 outputs, for example, (4, 3) indicating a set of the match distance and the match length.

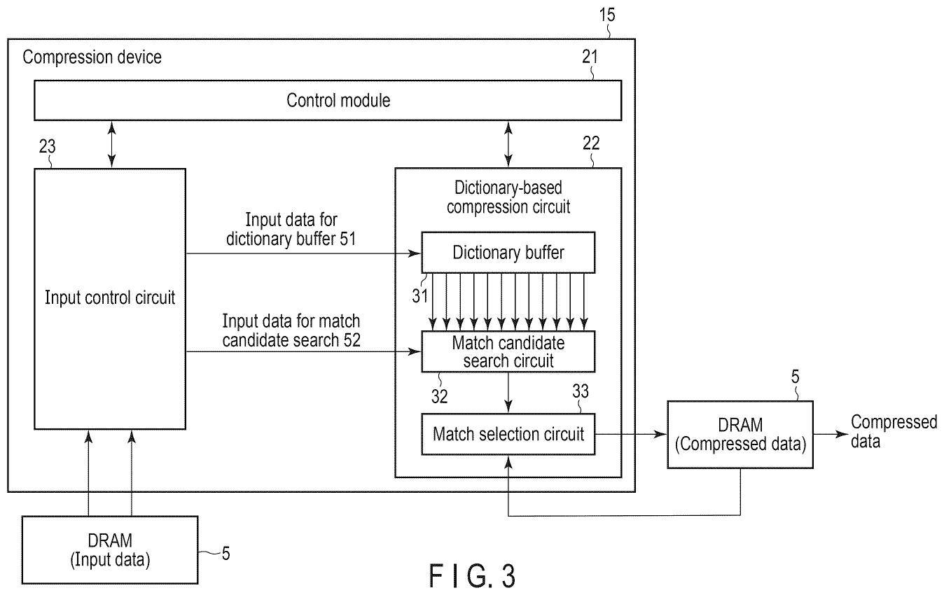

FIG. 3 is a block diagram showing an example of the configuration of the compression device 15. The compression device 15 includes a control module 21, the dictionary-based compression circuit 22, and an input control circuit 23. Moreover, the dictionary-based compression circuit 22 includes a dictionary buffer 31, a match candidate search circuit 32, and a match selection circuit 33. Note that, in the present embodiment, it is assumed that write data received in response to a write command from the host 2 is temporarily stored in the DRAM 5 as data to be compressed, but the write data may be stored in an SRAM or a DRAM built into the controller 6.

The control module 21 controls the operations of the dictionary-based compression circuit 22 and the input control circuit 23.

The dictionary-based compression circuit 22 performs dictionary-based compression on data to be compressed a plurality of times.

The input control circuit 23 acquires two types of input data, input data 51 for the dictionary buffer and input data 52 for match candidate search, from the DRAM 5, for example. The input data 51 for the dictionary buffer corresponds to past input data in current dictionary-based compression. The input data 52 for match candidate search corresponds to data to be compressed in current dictionary-based compression.

The input control circuit 23 acquires data to be compressed stored in the DRAM 5 as the input data 52 for match candidate search from a specified start position. More specifically, the input control circuit 23 acquires the data to be compressed stored in the DRAM 5 as the input data 52 for match candidate search from a start position that is shifted according to the number of times of data compression (the number of times of dictionary-based compression).

Furthermore, the input control circuit 23 acquires, as the input data 51 for the dictionary buffer, data having the same data length as the input data 52 for match candidate search from the head position of the data to be compressed stored in the DRAM 5.

The input control circuit 23 outputs the acquired input data 51 for the dictionary buffer to the dictionary buffer 31, and outputs the acquired input data 52 for match candidate search to the match candidate search circuit 32.

The dictionary buffer 31 is realized as, for example, a shift register. The dictionary buffer 31 buffers the dictionary buffer size of data among the input data 51 for the dictionary buffer, which is sequentially input from the input control circuit 23, as past input data (dictionary data).

The match candidate search circuit 32 uses the input data 52 for match candidate search, which is sequentially input from the input control circuit 23, as data to be compressed in current dictionary-based compression, searches the dictionary buffer size of past input data stored in the dictionary buffer 31, obtains past input data that at least partially matches the data to be compressed, and obtains a match distance and a match length.

When the match distance and match length are obtained, the match candidate search circuit 32 converts the data to be compressed in the current dictionary-based compression into a match symbol composed of the match distance and match length, and compresses the data to be compressed.

The data compressed by the match candidate search circuit 32 (compressed data) is output to the match selection circuit 33. When the match candidate search circuit 32 is unable to obtain a match distance and a match length, that is, when past data that at least partially matches the data to be compressed in the current dictionary-based compression is not stored in the dictionary buffer 31, the match candidate search circuit 32 outputs the data to be compressed intact to the match selection circuit 33.

The match selection circuit 33 writes the result of the initial dictionary-based compression output from the match candidate search circuit 32 to the DRAM 5, for example. More specifically, the match selection circuit 33 writes the compressed data resulting from the initial dictionary-based compression output from the match candidate search circuit 32 to the DRAM 5, or writes the data to be compressed in the initial dictionary-based compression output from the match candidate search circuit 32 to the DRAM 5.

In the second and subsequent dictionary-based compressions, the match selection circuit 33 compares the size of the compressed data resulting from the current dictionary-based compression output from the match candidate search circuit 32 with the size of the compressed data resulting from past dictionary-based compression obtained from the DRAM 5, and writes the compressed data having a smaller data size to the DRAM 5 as compressed data with a better compression ratio.

In a case where the data to be compressed is write data received in response to reception of a write command from the host 2, when a series of compression processing performed by the compression device 15 is completed, the controller 6 executes processing of reading the compressed data written to the DRAM 5 and writing the compressed data to the NAND flash memory 4. When the compressed data is stored in the NAND flash memory 4, predetermined processing such as error correction processing or randomization processing may be executed. In this case, the CPU 11 writes the data obtained by executing the predetermined processing on the compressed data to the NAND flash memory 4 via the NAND I/F 12. That is, the CPU 11 writes data based on the compressed data to the NAND flash memory 4. In this case, when the CPU 11 reads the compressed data from the NAND flash memory 4, the CPU 11 reads data based on a read command from the host 2 from the NAND flash memory 4 via the NAND I/F 12. The data read from the NAND flash memory 4 is subjected to predetermined processing such as error correction processing and randomization cancellation processing, and then stored in the DRAM 5 by the CPU 11 as compressed data. The compressed data stored in the DRAM 5 is input by the CPU 11 to a decoding circuit that is not shown. The decoding circuit is built into the controller 6, for example, and decompresses the input compressed data to generate decompressed data (decoded data). That is, the decoding circuit decompresses the compressed data based on the data read from the NAND flash memory 4 to generate decompressed data (decoded data).

Components in the compression device 15 are realized by at least one of a register, a memory, an adder, a multiplier, a selector, and other arithmetic units, for example. The register is realized by a sequential circuit such as a flip-flop. The memory is realized by a storage element such as an SRAM or a DRAM. The adder, the multiplier, the selector, and other arithmetic units are realized by a combinational logic circuit, for example.

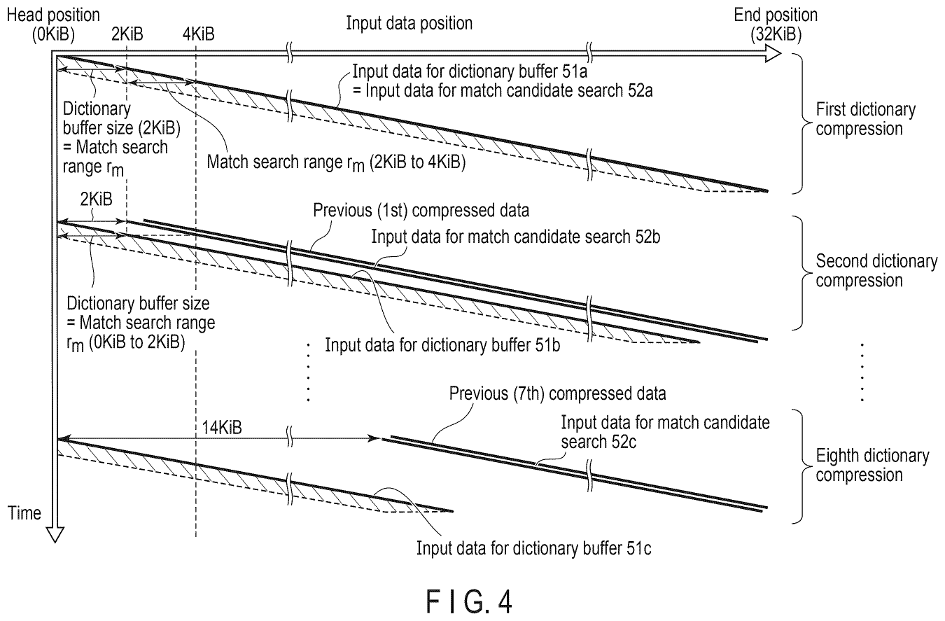

Now, compression processing executed in the compression device 15 according to the present embodiment will be specifically described with reference to FIG. 4. The vertical axis of the graph shown in FIG. 4 indicates the time from when input of various types of data starts, and the horizontal axis indicates the positions of the various types of data. Note that FIG. 4 assumes a case in which the data length of data to be compressed is 32 KiB and the dictionary buffer size of the dictionary buffer 31 is 2 KiB. In addition, compression processing described below is executed by the control module 21 of the compression device 15 controlling the operations of the dictionary-based compression circuit 22 and the input control circuit 23.

In this case, in the first dictionary-based compression (initial dictionary-based compression), the input control circuit 23 acquires data to be compressed that has a data length of 32 KiB and is stored in the DRAM 5 from the head position, as input data 51a for the dictionary buffer and input data 52a for match candidate search.

The acquired input data 51a for the dictionary buffer and input data 52a for match candidate search are output by input control circuit 23 to the dictionary buffer 31 and the match candidate search circuit 32 at the same timing.

The dictionary buffer 31 buffers 2 KiB of input data among the input data 51a for the dictionary buffer, which is sequentially input from the input control circuit 23, as past input data. For example, when data up to the position of 2 KiB position of the input data 51a for the dictionary buffer, which has a data length of 32 KiB, has been input to the dictionary buffer 31, the dictionary buffer 31 buffers data corresponding to the range from 0 KiB to 2 KiB as past input data. Further, when data up to the position of 3 KiB of the input data 51 a for the dictionary buffer, which has a data length of 32 KiB, has been input to the dictionary buffer 31, the dictionary buffer 31 buffers data corresponding to the range from 1 KiB to 3 KiB as past input data. In this way, the dictionary buffer 31 buffers 2 KiB (dictionary buffer size) of data from the data corresponding to the latest input position among the input data 51a sequentially input from the input control circuit 23.

The match candidate search circuit 32 uses the input data 52a for match candidate search, which is sequentially input from the input control circuit 23, as data to be compressed in the first dictionary-based compression, and searches 2 KiB of past input data stored in the dictionary buffer 31.

In the first dictionary-based compression, a range going back 2 KiB from the data corresponding to the latest input position among the input data 52a sequentially input from the input control circuit 23 becomes a match search range rm, and as the input data 52a is sequentially input, this match search range rm slides. For example, as shown in FIG. 4, when data up to a position of 4 KiB among the input data 52a for match candidate search having a data length of 32 KiB has been input to the match candidate search circuit 32, the match candidate search circuit 32 searches for past input data corresponding to a range from 2 KiB to 4 KiB stored in the dictionary buffer 31 at this point in time as past input data that at least partially matches the data corresponding to the position of 4 KiB.

In the first dictionary-based compression, since there is no past compressed data stored in the DRAM 5, the match selection circuit 33 writes the result of the first dictionary-based compression (compressed data) output from the match candidate search circuit 32 to the DRAM 5.

In the second dictionary-based compression (first re-compression), the input control circuit 23 acquires, as the input data 52b for match candidate search, data to be compressed having a data length of 32 KiB from a start position shifted by 2 KiB (the dictionary buffer size). That is, the input control circuit 23 acquires data having a data length of 30 KiB, starting from the position of 2 KiB as the start position as the input data 52b for match candidate search in the second dictionary-based compression.

In addition, the input control circuit 23 acquires data having the same data length as the input data 52b for match candidate search (i.e., data having a data length of 30 KiB) from the head position of the data to be compressed having a data length of 32 KiB, as input data 51b for the dictionary buffer in the second dictionary-based compression. That is, the input control circuit 23 acquires data having a data length of 30 KiB, starting from the position of 0 KiB, as the input data 51b for the dictionary buffer in the second dictionary-based compression.

The acquired input data 51b for the dictionary buffer and input data 52b for match candidate search are output by the input control circuit 23 to the dictionary buffer 31 and the match candidate search circuit 32 at the same timing.

As in the first dictionary-based compression, the dictionary buffer 31 buffers 2 KiB of input data among the input data 51b for the dictionary buffer sequentially input from the input control circuit 23 as past input data.

As in the first dictionary-based compression, the match candidate search circuit 32 uses the input data 52b for match candidate search sequentially input from the input control circuit 23 as data to be compressed in the second dictionary-based compression, and searches for 2 KiB of past input data stored in the dictionary buffer 31. For example, as shown in FIG. 4, when data up to the position corresponding to 4 KiB among the input data 52b for match candidate search having a data length of 30 KiB has been input to the match candidate search circuit 32, the match candidate search circuit 32 searches for past input data corresponding to a range from 0 KiB to 2 KiB stored in the dictionary buffer 31 at this point in time as past input data that at least partially matches the data corresponding to the position of 4 KiB.

According to this, with respect to the data corresponding to the position of 4 KiB in the data to be compressed having a data length of 32 KiB, the match candidate search circuit 32 can search for past input data corresponding to a range of 2 KiB to 4 KiB in the first dictionary-based compression, and can search for past input data corresponding to a range of 0 KiB to 2 KiB in the second dictionary-based compression. That is, the match candidate search circuit 32 can compress the data corresponding to the position of 4 KiB based on the past input data corresponding to the range of 2 KiB to 4 KiB in the first dictionary-based compression, and can compress the data corresponding to the position of 4 KiB based on the past input data corresponding to the range of 0 KiB to 2 KiB in the second dictionary-based compression.

The match selection circuit 33 acquires, from the DRAM 5, compressed data in the first dictionary-based compression that corresponds to the start position of the data to be compressed in the second dictionary-based compression (the input data 52b for match candidate search), compares the size of the acquired compressed data in the first dictionary-based compression with the size of the compressed data in the second dictionary-based compression, and writes the compressed data having a smaller data size to the DRAM 5 as compressed data having a better compression ratio. For example, when the size of the compressed data in the second dictionary-based compression is smaller than the size of the compressed data in the first dictionary-based compression, the match selection circuit 33 rewrites the compressed data from the start position of the data to be compressed in the second dictionary-based compression among the compressed data in the first dictionary-based compression stored in the DRAM 5 to the compressed data in the second dictionary-based compression. Note that in FIG. 4, for convenience of description, the start positions of the input data 52b for match candidate search and the previous (first) compressed data are shifted, but in reality, the start positions of the input data 52b for match candidate search and the first compressed data are the same.

As described above, according to the compression device 15 of the present embodiment, by performing dictionary-based compression twice, for example, it is possible to compare data corresponding to the position of 4 KiB with past input data corresponding to the range from 0 KiB to 4 KiB, and to realize searching equivalent to matching search using a dictionary buffer size that is logically twice as large (i.e., a dictionary buffer size of 4 KiB).

Note that the data length of the input data 51a for the dictionary buffer and the input data 52a for match candidate search in the first dictionary-based compression is 32 KiB, whereas the data length of the input data 51b for the dictionary buffer and the input data 52b for match candidate search in the second dictionary-based compression is 30 KiB, which is shorter by the dictionary buffer size (i.e., 2 KiB), and thus the total processing time required for two dictionary-based compressions is shorter than simply doubling the time required for the first dictionary-based compression. That is, according to the compression device 15 of the present embodiment, it is possible to double the logical dictionary buffer size while shortening the total processing time required for compression processing compared to the total processing time required to simply perform two dictionary-based compressions.

Generally, a dictionary-based compression circuit that performs dictionary-based compression increases in circuit size as the dictionary buffer size increases. However, the compression device 15 having the dictionary-based compression circuit 22 according to the present embodiment can improve the compression ratio while suppressing an increase in circuit size by logically expanding the dictionary buffer size. As described above, it is possible to reduce the total processing time required for compression processing to be shorter than the time required for the first dictionary-based compression (normal dictionary-based compression) that is simply multiplied by the number of times.

Note that recompression is performed, for example, a predetermined number of times. In FIG. 4, for example, it is assumed that seven recompressions (i.e., eight dictionary-based compressions) are performed.

As with the second dictionary-based compression, the input control circuit 23 also obtains input data 52 for match search candidates in the third to eighth dictionary-based compressions from a start position shifted by 2 KiB (dictionary buffer size) for each recompression from the data to be compressed, which has a data length of 32 KiB. For example, in the eighth dictionary-based compression, the input control circuit 23 acquires data whose start position has been shifted by “the number of times dictionary-based compression is repeated×dictionary buffer size”, specifically, data having a data length of 18 KiB, starting from the position of 14 (=7×2) KiB, as input data 52c for match candidate search.

Furthermore, the input control circuit 23 acquires data of the same data length as the input data 52c for match candidate search (i.e., data having a data length of 18 KiB) from the start position of the data to be compressed having a data length of 32 KiB, as input data 51c for the dictionary buffer in the eighth dictionary-based compression. That is, the input control circuit 23 acquires data having a data length of 18 KiB, starting from the position of 0 KiB, as the input data 51c for the dictionary buffer in the eighth dictionary-based compression.

The acquired input data 51c for the dictionary buffer and input data 52c for match candidate search are output by the input control circuit 23 to the dictionary buffer 31 and the match candidate search circuit 32 at the same timing.

As with the first and second dictionary-based compressions, the dictionary buffer 31 buffers 2 KiB of input data among the input data 51c for the dictionary buffer that is sequentially input from the input control circuit 23 as past input data.

As with the first and second dictionary-based compressions, the match candidate search circuit 32 uses the input data 52c for match candidate search that is sequentially input from the input control circuit 23 as data to be compressed in the eighth dictionary-based compression, and searches for 2 KiB of past input data stored in the dictionary buffer 31. For example, as shown in FIG. 4, when data up to the position of 16 KiB among the input data 52c for match candidate search, which has a data length of 18 KiB, has been input to the match candidate search circuit 32, the match candidate search circuit 32 searches for past input data corresponding to the range from 0 KiB to 2 KiB stored in the dictionary buffer 31 at this point in time as past input data that at least partially matches the data corresponding to the position of 16 KiB.

This allows the match candidate search circuit 32 to search for past input data corresponding to the range from 0 KiB to 16 KiB in the first to eighth dictionary-based compressions with respect to data corresponding to the position of 16 KiB in the data to be compressed, which has a data length of 32 KiB.

The match selection circuit 33 acquires, from the DRAM 5, compressed data in the seventh dictionary-based compression that corresponds to the start position of the data to be compressed in the eighth dictionary-based compression (input data 52c for match candidates search), compares the size of the acquired compressed data in the seventh dictionary-based compression with the size of the compressed data in the eighth dictionary-based compression, and writes the compressed data having smaller data size to the DRAM 5 as compressed data having a better compression ratio. Note that, for convenience of description, in FIG. 4, the start positions of the input data 52c for match candidate search and the previous (seventh) compressed data are shifted, but in reality, the start positions of the input data 52c for match candidate search and the seventh compressed data are the same.

As described above, according to the compression device 15 of the present embodiment, by performing dictionary-based compression eight times, for example, it is possible to compare data corresponding to the position of 16 KiB with past input data corresponding to the range from 0 KiB to 16 KiB, and to realize searching that is logically equivalent to matching search using a dictionary buffer size that is eight times larger (i.e., a dictionary buffer size of 16 KiB).

The data length of the input data 52 for match candidate search is 32 KiB in the first dictionary-based compression, 30 KiB in the second dictionary-based compression, 28 KiB in the third dictionary-based compression, 26 KiB in the fourth dictionary-based compression, 24 KiB in the fifth dictionary-based compression, 22 KiB in the sixth dictionary-based compression, 20 KiB in the seventh dictionary-based compression, and 18 KiB in the eighth dictionary-based compression. That is, the total data length of the input data 52 for match candidate search that has been compressed in eight dictionary-based compressions is 200 (=32+30+ . . . +20+18) KiB, which is 6.25 (=200÷32) times the data length of the input data 52a for match candidate search in the first dictionary-based compression (normal dictionary-based compression), and the total processing time required for eight dictionary-based compressions is also 6.25 times. However, as described above, the total processing time required for eight dictionary-based compressions is eight times the processing time required for one dictionary-based compression when dictionary-based compression has been performed simply eight times, but the compression device 15 according to the present embodiment can perform processing in 6.25 times which is shorter than the normal time.

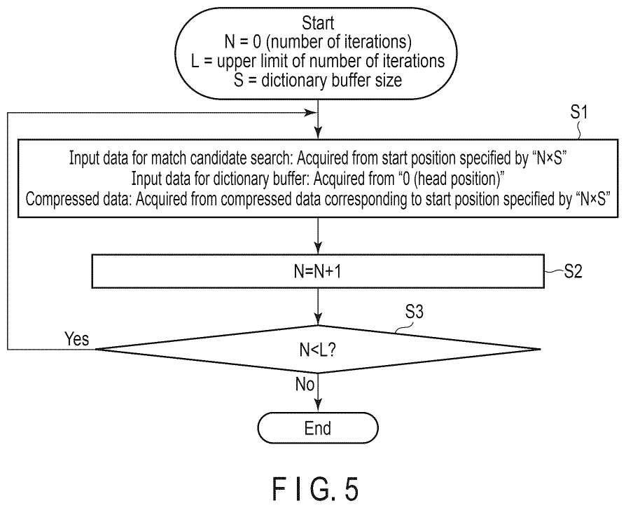

FIG. 5 is a flowchart showing an example of a procedure of compression processing executed by the compression device 15 according to the present embodiment. A series of compression processing shown in FIG. 5 are executed by the control module 21 of the compression device 15 controlling the operations of the circuits 31, 32, and 33 included in the dictionary-based compression circuit 22 and the input control circuit 23. Note that “N” in FIG. 5 indicates the number of repetitions (number of recompressions) of dictionary-based compression executed by the compression device 15, for example, N is 0 in the case of the first dictionary-based compression, and N is 1 in the case of the second dictionary-based compression. Further, in FIG. 5, “L” indicates the upper limit of the number of repetitions of dictionary-based compression, and “S” indicates the dictionary buffer size of the dictionary buffer 31.

The control module 21 of the compression device 15 controls the input control circuit 23 to acquire data to be compressed stored in the DRAM 5 as input data 52 for match candidate search from a start position specified by “N×S”. Further, the control module 21 of the compression device 15 controls the input control circuit 23 to acquire, as input data 51 for the dictionary buffer, data to be compressed, starting from “0 (head position)”, in the same length as the input data 52 for match candidate search in the current dictionary-based compression. Furthermore, the control module 21 of the compression device 15 controls the match selection circuit 33 to acquire, as compressed data for comparison which will be described later, compressed data corresponding to the start position specified by “N×S” (step S1).

For example, in the case of the first dictionary-based compression, the control module 21 of the compression device 15 controls the input control circuit 23 to acquire, as the input data 52 for match candidate search, data to be compressed, starting from the start position (i.e., head position) specified by “0×S”. Furthermore, the control module 21 of the compression device 15 controls the input control circuit 23 to acquire, as the input data 51 for the dictionary buffer, data to be compressed, starting from “0 (head position)”, in the same length as the input data 52 for match candidate search in the first dictionary-based compression. In the first dictionary-based compression, there is no compressed data for comparison yet, and thus processing of obtaining compressed data in processing of step S1 is omitted.

In addition, in the case of the second dictionary-based compression, the control module 21 of the compression device 15 controls the input control circuit 23 to acquire, as input data 52 for match candidate search, data to be compressed from a start position specified by “1×S” (i.e., a position shifted by the dictionary buffer size S from the head position). Furthermore, the control module 21 of the compression device 15 controls the input control circuit 23 to acquire, as the input data 51 for the dictionary buffer, data to be compressed, starting from “0 (head position)”, in the same length as the input data 52 for match candidate search in the first dictionary-based compression. Furthermore, the control module 21 of the compression device 15 controls the match selection circuit 33 to acquire compressed data corresponding to the start position specified by “1×S” as compressed data for comparison.

The compression device 15 compresses the data to be compressed (input data 52 for match candidate search) in the current dictionary-based compression based on the input data 52 for match candidate search and the input data 51 for the dictionary buffer acquired by processing of step S1 to generate compressed data. The data size of the generated compressed data is compared with the size of the compressed data acquired by processing of step S1, and the compressed data having the better compression ratio is stored in the DRAM 5. Processing of generating and comparing the compressed data and writing the compressed data having the better compression ratio to the DRAM 5 is executed by the control module 21 of the compression device 15 controlling the circuits 31, 32, and 33 included in the dictionary-based compression circuit 22.

After the current dictionary-based compression, the control module 21 of the compression device 15 adds 1 to the number of repetitions N of dictionary-based compression (step S2), and determines whether or not the number of repetitions N of dictionary-based compression is less than the upper limit L (i.e., whether or not the number of repetitions N of dictionary-based compression has reached the upper limit L) (step S3).

When it is determined in processing of step S3 that the number of repetitions N of dictionary-based compression is less than the upper limit L and has not yet reached the upper limit L (Yes in step S3), the control module 21 of the compression device 15 executes processing of step S1 again. On the other hand, when it is determined in processing of step S3 that the number of repetitions N of dictionary-based compression is equal to or greater than the upper limit L and has reached the upper limit L (No in step S3), the control module 21 of the compression device 15 ends the series of compression processing.

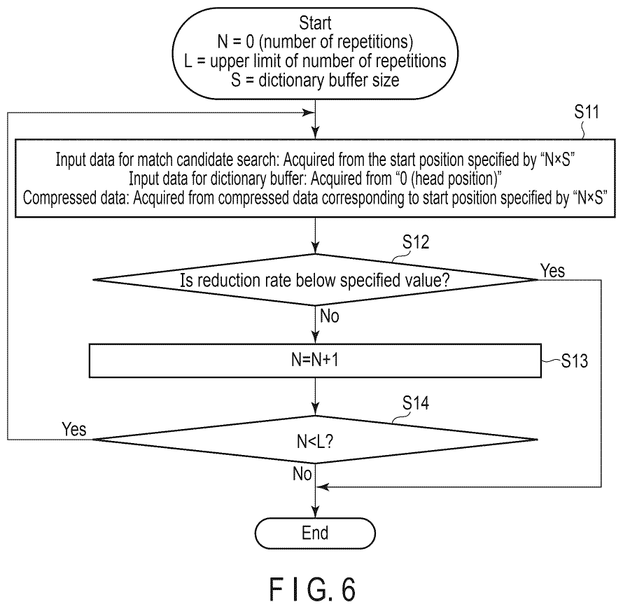

Note that, although FIG. 5 illustrates an example of compression processing in which dictionary-based compression is repeated a predetermined number of times up to the upper limit L, the present invention is not limited thereto, and the compression device 15 according to the present embodiment may execute, for example, compression processing shown in FIG. 6.

Hereinafter, another example of compression processing executed by the compression device 15 according to the present embodiment will be described with reference to the flowchart in FIG. 6. Note that a series of compression processing shown in FIG. 6 are executed by the control module 21 of the compression device 15 controlling the operations of the circuits 31, 32, and 33 included in the dictionary-based compression circuit 22 and the input control circuit 23, similar to the compression processing shown in FIG. 5. Further, “N” in FIG. 6 indicates the number of repetitions (number of recompressions) of dictionary-based compression performed by the compression device 15, similar to the case of FIG. 5. Furthermore, in FIG. 6, “L” indicates the upper limit of the number of repetitions of dictionary-based compression, similar to the case of FIG. 5, and “S” in FIG. 6 also indicates the dictionary buffer size of the dictionary buffer 31, similar to the case of FIG. 5.

First, the control module 21 of the compression device 15 controls the input control circuit 23 to acquire, as input data 52 for match candidate search, data to be compressed stored in the DRAM 5 from a start position specified by “N×S”, as in processing of step S1 of FIG. 5. Further, the control module 21 of the compression device 15 controls the input control circuit 23 to acquire, as input data 51 for the dictionary buffer, data to be compressed, starting from “0 (head position)”, in the same length as the input data 52 for match candidate search in the current dictionary-based compression. Furthermore, the control module 21 of the compression device 15 controls the match selection circuit 33 to acquire compressed data corresponding to the start position specified by “N×S” as compressed data for comparison (step S11).

The compression device 15 compresses the data to be compressed in the current dictionary-based compression (input data 52 for match candidate search) based on the input data 52 for match candidate search and the input data 51 for the dictionary buffer acquired by processing of step S11 to generate compressed data. The data size of the generated compressed data is compared with the size of the compressed data acquired by the processing of step S11, and the compressed data having the better compression ratio is stored in the DRAM 5. Processing of generating and comparing the compressed data and writing the compressed data having the better compression ratio to the DRAM 5 is executed by the control module 21 of the compression device 15 controlling the circuits 31, 32, and 33 included in the dictionary-based compression circuit 22.

Here, the control module 21 of compression device 15 determines whether or not a data reduction rate in the current dictionary-based compression is equal to or less than a predetermined value (step S12). The data reduction rate is a value calculated based on the size of compressed data in the current dictionary-based compression and the size of compressed data in the previous dictionary-based compression, and is a value defined by, for example, “1−{(size of compressed data in current dictionary-based compression)/(size of compressed data in previous dictionary-based compression)}”.

When it is determined in processing of step S12 that the data reduction rate is equal to or less than the predetermined value (Yes in step S12), the control module 21 of the compression device 15 ends the series of compression processing before the number of repetitions N of dictionary-based compression reaches the upper limit L.

On the other hand, when it is determined in processing of step S12 that the data reduction rate is not equal to or less than the predetermined value, that is, is greater than the predetermined value (No in step S12), the control module 21 of the compression device 15 adds 1 to the number of repetitions N of dictionary-based compression (step S13), as in processing of steps S2 and S3 of FIG. 5, and determines whether or not the number of repetitions N of dictionary-based compression is less than the upper limit L (that is, whether or not the number of repetitions N of dictionary-based compression has reached the upper limit L) (step S14).

In processing of step S14, when it is determined that the number of repetitions N of dictionary-based compression is less than the upper limit L and has not yet reached the upper limit L (Yes in step S14), the control module 21 of the compression device 15 executes processing of step S11 again. On the other hand, when it is determined that the number of repetitions N of dictionary-based compression is equal to or greater than the upper limit L and has reached the upper limit L in processing of step S14 (No in step S14), the control module 21 of the compression device 15 ends the series of compression processing.

In general, in dictionary-based compression, it is known that the compression effect decreases as a match search range is farther away from the position of data to be compressed. According to processing of step S12 described above, it is determined whether or not the compression effect is low, and when it is determined that the compression effect is low, the subsequent processing can be omitted, and thus the total processing time can be reduced and compressed data can be generated more efficiently.

The data reduction rate may be a value defined by, for example, “1−{(size of compressed data in current dictionary-based compression)/(size of compressed data in dictionary-based compression before previous dictionary-based compression)}” instead of “1−{(size of compressed data in current dictionary-based compression)/(size of compressed data in previous dictionary-based compression)}”. In this case, the compression device 15 needs to store information indicating the size of the compressed data in dictionary-based compression before the previous dictionary-based compression in addition to the size of the compressed data in the previous dictionary-based compression in the DRAM 5, but by performing dictionary-based compression that happens to not reduce data once, it is possible to reduce the possibility that dictionary-based compression that could have reduced data will not be performed thereafter.

The compression device 15 according to the first embodiment described above includes the dictionary buffer 31, the match candidate search circuit 32, and the match selection circuit 33, and is equipped with the dictionary-based compression circuit 22 that performs dictionary-based encoding on data to be compressed a plurality of times, and the input control circuit 23 that outputs input data based on the data to be compressed to the dictionary-based compression circuit 22.

The input control circuit 23 outputs the data to be compressed from a specified start position to the match candidate search circuit 32 as input data 52 for match candidate search, and outputs the data to be compressed from the head position to the dictionary buffer 31 as input data 51 for the dictionary buffer having the same length as the input data 52 for match candidate search. The dictionary buffer 31 stores, as dictionary data, data of the dictionary buffer size from the input data 51 for the dictionary buffer sequentially input from the input control circuit 23. The match candidate search circuit 32 acquires dictionary data that at least partially matches the input data 52 for match candidate search sequentially input from the input control circuit 23, and generates compressed data by current dictionary-based encoding. When there is compressed data previously generated by the match candidate search circuit 32, the match selection circuit 33 compares the size of the compressed data generated by the current dictionary-based encoding with the size of the compressed data previously generated and corresponding to the currently specified start position, and outputs compressed data having a smaller size. When there is no compressed data previously generated by the match candidate search circuit 32, the match selection circuit 33 outputs the compressed data generated by the current dictionary-based encoding.

This makes it possible to logically expand the dictionary buffer size and improve the compression ratio while suppressing an increase in circuit scale.

In the present embodiment, the amount by which the start position of the input data 52 for match candidate search is shifted is the dictionary buffer size, but the amount by which the start position of the input data 52 for match candidate search is shifted does not have to be the dictionary buffer size. For example, in the case in which a position where similar data is likely to be present in data to be compressed is known in advance, the start position of the input data 52 for match candidate search can be shifted to that position at once, thereby reducing the total processing time required for compression processing.

### Second Embodiment

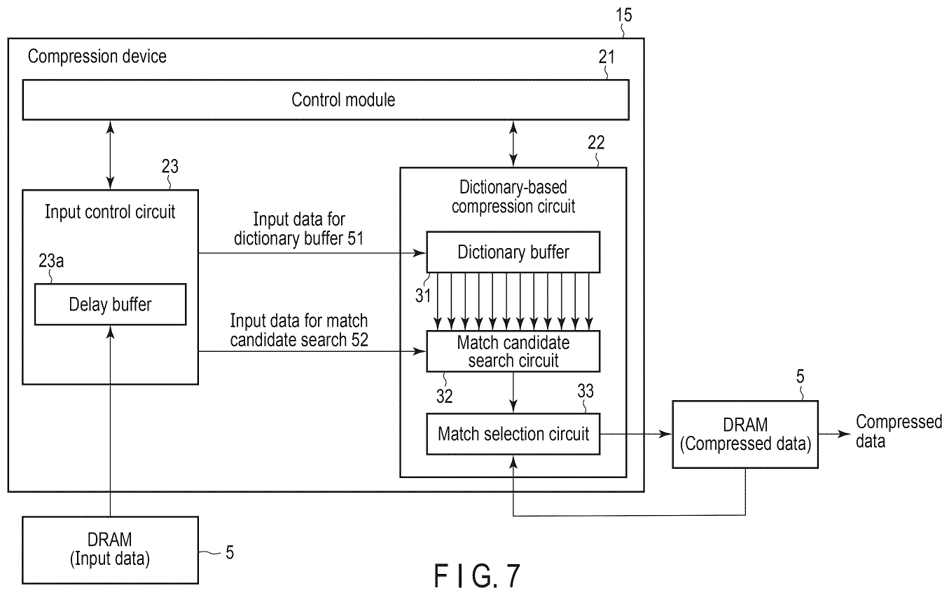

A second embodiment will be described. The configuration according to the second embodiment differs from the configuration according to the first embodiment in that the input control circuit 23 includes a delay buffer 23a, as shown in FIG. 7. In the following, only the differences from the first embodiment will be described, and description of the same points as the first embodiment will be omitted.

The delay buffer 23a is realized, for example, as an SRAM. The delay buffer 23a delays data to be compressed, which is sequentially acquired from the DRAM 5, by a delay amount set in the delay buffer 23a, and outputs the delayed data to the dictionary buffer 31 as input data 51 for the dictionary buffer.

The delay amount set in the delay buffer 23a is changed every time dictionary-based compression is performed in the dictionary-based compression circuit 22.

For example, when the compression device 15 executes the series of compression processing shown in FIG. 5, in the first dictionary-based compression, the input control circuit 23 acquires data to be compressed from the same start position as the input data 51 for the dictionary buffer and the input data 52 for match candidate search, and thus the delay amount of the delay buffer 23a is set to 0 (zero). In the second dictionary-based compression, the input control circuit 23 acquires data to be compressed from the start position specified by “1×S” as the input data 52 for match candidate search, and thus the delay amount of the delay buffer 23a is set to the dictionary buffer size. Furthermore, in the third dictionary-based compression, the input control circuit 23 acquires data to be compressed from the start position specified by “2×S” as the input data 52 for match search, and thus the delay amount of the delay buffer 23a is set to twice the dictionary buffer size. In this way, the delay amount set in the delay buffer 23a is set according to the shift amount of the input data 52 for match candidate search.

In the case of the configuration of the first embodiment, in the second and subsequent dictionary-based compressions (recompressions), the input control circuit 23 needs to obtain from the DRAM 5 two types of data, the input data 51 for the dictionary buffer and the input data 52 for match candidate search, which have different start positions, which consumes twice the DRAM bandwidth of normal dictionary-based compression.

On the other hand, according to the configuration of the second embodiment, the input control circuit 23 can delay the input data 51 for the dictionary buffer by the delay amount set in the delay buffer 23a, and thus it is possible to output the input data 51 for the dictionary buffer and the input data 52 for match candidate search, which have different start positions, to the dictionary-based compression circuit 22 by simply obtaining one type of data from the DRAM 5, and consumption of the DRAM bandwidth can be reduced to half of that in the configuration of the first embodiment (i.e., equivalent to that of normal dictionary-based compression).

However, the configuration according to the second embodiment is applicable only when the logical dictionary buffer size of the dictionary-based compression circuit 22 (in other words, match search ranges in a plurality of dictionary-based compressions), which changes according to the upper limit of the number of repetitions of dictionary-based compression, is set to equal to or less than “delay buffer size+dictionary buffer size”.

### Third Embodiment

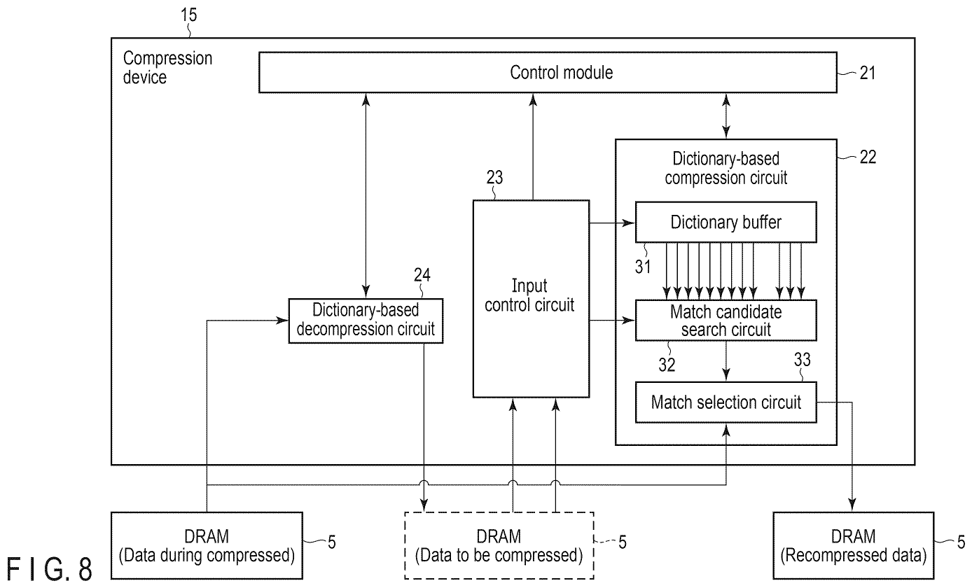

A third embodiment will be described. The configuration according to the third embodiment differs from the configuration according to the first embodiment in that the compression device 15 further includes a dictionary-based decompression circuit 24, as shown in FIG. 8. In the following, only the differences from the first embodiment will be described, and description of the same points as the first embodiment will be omitted.

For example, when it is necessary to compress other data to be compressed before first data to be compressed is recompressed after compressed at least once in the compression device 15, it is necessary to store both the first data to be compressed and the compressed data obtained by compressing the first data to be compressed at least once (hereinafter referred to as data being compressed) in the DRAM 5 as data related to the first data to be compressed. In this way, leaving data that is not immediately used stored in the DRAM 5 burdens the capacity (memory usage) of the DRAM 5, which is inefficient.

Therefore, the compression device 15 of the present embodiment further includes the dictionary-based decompression circuit 24, and when it is necessary to compress other data to be compressed before first data to be compressed is recompressed after compressed, only the data being compressed as described above is stored in the DRAM 5 and the first data to be compressed is discarded (deleted) from the DRAM 5, making the DRAM 5 available for compressing the other data to be compressed.

When only the data being compressed is stored in the DRAM 5 and the first data to be compressed is discarded from the DRAM 5, the compression device 15 needs to store information capable of specifying how much the start position of the input data 52 for match candidate search should be shifted at the time of recompression, for example, in the DRAM 5. The information capable of specifying how much the start position of the input data 52 for match candidate search should be shifted at the time of recompression is, for example, information indicating the size of the logical dictionary buffer in the current dictionary-based compression. Accordingly, the compression device 15 can specify that the start position of the input data 52 for match candidate search should be shifted by the size of the logical dictionary buffer indicated by the above-mentioned information at the time of recompression.

The above-mentioned information is sufficiently small in size compared to the first data to be compressed, and does not burden the capacity of the DRAM 5. Further, the information capable of specifying how much the start position of the input data 52 for match candidate search should be shifted at the time of recompression may be included as a header in the data being compressed.

The operation of the dictionary-based decompression circuit 24 is controlled by the control module 21. The dictionary-based decompression circuit 24 decompresses input compressed data and returns the compressed data to the original data (i.e., the first data to be compressed). The data decompressed by the dictionary-based decompression circuit 24 is temporarily stored in the DRAM 5 as data that can be acquired by the input control circuit 23. In this way, even if first data to be compressed is discarded from the DRAM 5 between compression of the first data to be compressed and recompression of the first data to be compressed, the input control circuit 23 can acquire the first data to be compressed that has been decompressed by the dictionary-based decompression circuit 24 at the time of recompression, and the compression device 15 can recompress the first data to be compressed.

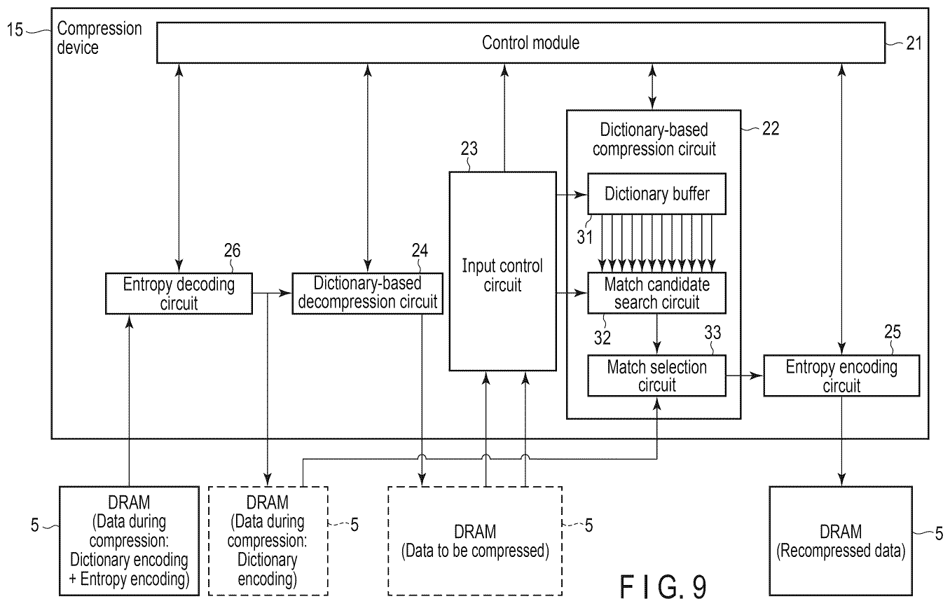

The configuration according to the third embodiment is not limited to the configuration shown in FIG. 8, and may be, for example, the configuration shown in FIG. 9. The configuration shown in FIG. 9 differs from the configuration shown in FIG. 8 in that the compression device 15 further includes an entropy encoding circuit 25 and an entropy decoding circuit 26.

The operations of the entropy encoding circuit 25 and the entropy decoding circuit 26 are controlled by the control module 21.

The entropy encoding circuit 25 performs entropy encoding on the result of dictionary-based compression (i.e., the compressed data generated by the current dictionary-based compression) output from the match selection circuit 33 to generate compressed data.

Entropy encoding is a variable-length encoding method that dynamically generates a code table (encoding table) using the frequency of occurrence of symbols to be encoded. Entropy encoding is defined by, for example, deflate or gzip. The code table includes information indicating n types of symbols and n code words respectively associated with the n types of symbols. In entropy encoding, short code words are assigned to symbols that occur frequently, and long code words are assigned to symbols that occur infrequently. The entropy encoding circuit 25 converts input symbols into code words in accordance with such assignment. That is, the code words obtained by conversion are variable-length codes.

Symbols are, for example, fixed-length data. The compressed data generated by entropy encoding includes code words obtained by converting each of a plurality of match symbols included in the result of dictionary-based compression. The compressed data generated by entropy encoding may further include data of the code table used for entropy encoding as a header. The data of the code table is used to restore the code table (decoding table) when the compressed data generated by entropy encoding is decompressed.

In this case, it is assumed that other data to be compressed needs to be compressed before first data to be compressed is recompressed after compressed, and thus the compressed data generated by performing dictionary-based compression (dictionary-based encoding) and entropy encoding on the first data to be compressed is stored in the DRAM 5 as data being compressed, and the first data to be compressed is discarded from the DRAM 5.

The entropy decoding circuit 26 restores a restoration table from the data of the code table included as the header in the compressed data generated by entropy encoding, and decodes the result of dictionary-based compression (i.e., the compressed data generated by dictionary-based compression) from the compressed data based on the restoration table. The compressed data (data being compressed) decoded by the entropy decoding circuit 26 is output to the dictionary-based decompression circuit 24 and is temporarily stored in the DRAM 5 as data that can be acquired by the match selection circuit 33.

Processing executed by the dictionary-based decompression circuit 24 using the data being compressed output from the entropy decoding circuit 26 is similar to the configuration in FIG. 8, and thus detailed description is omitted here.

The configuration shown in FIG. 9 can reduce memory usage even more than the configuration shown in FIG. 8.

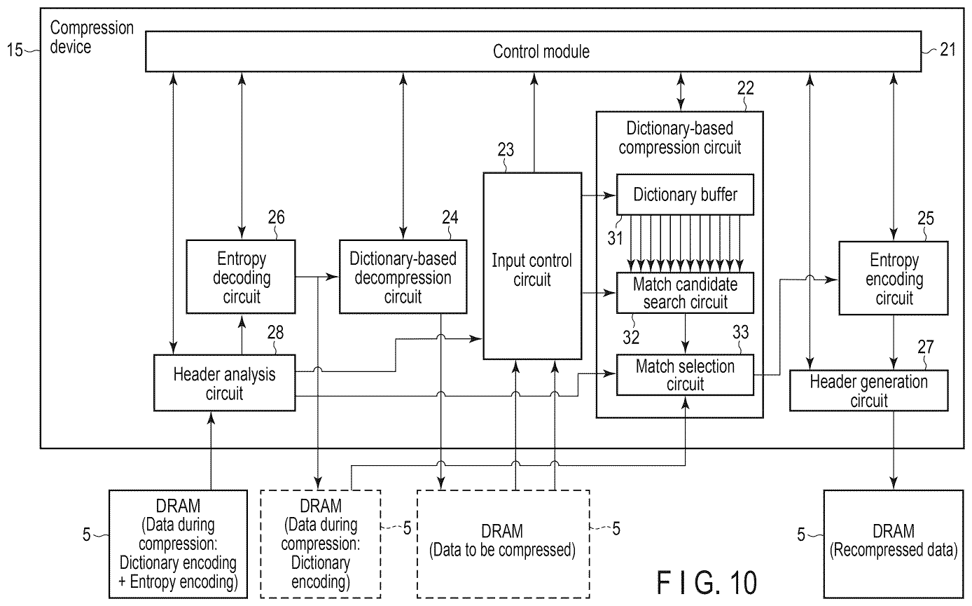

Further, the configuration according to the third embodiment is not limited to the configuration shown in FIG. 8 and FIG. 9, and may be, for example, the configuration shown in FIG. 10. The configuration shown in FIG. 10 differs from the configuration shown in FIG. 9 in that the compression device 15 further includes a header generation circuit 27 and a header analysis circuit 28.

The operations of the header generation circuit 27 and the header analysis circuit 28 are controlled by the control module 21.

The header generation circuit 27 embeds (includes) information capable of specifying how much the start position of the input data 52 for match candidate search should be shifted at the time of recompression in the header of the data being compressed. In addition, the header analysis circuit 28 analyzes the information embedded in the header of the data being compressed, and outputs a value indicating the amount of shift of the start position of the input data 52 for match candidate search to the input control circuit 23. Note that processing executed in the other circuits have been described above, and therefore detailed description will be omitted here.

The configuration shown in FIG. 10 is easier to incorporate into a system than the configuration in which the information capable of specifying how much the start position of the input data 52 for match candidate search should be shifted at the time of recompression is stored in the DRAM 5.

Note that the header generation circuit 27 may embed, for example, a flag indicating that recompression is required (recompression flag) in the header of the data being compressed, instead of embedding the information capable of specifying how much the start position of the input data 52 for match candidate search should be shifted at the time of recompression. In this case, the header analysis circuit 28 analyzes the header of the data during compressed, and when it is confirmed that the data being compressed needs to be recompressed and that the header does not include the information capable of specifying how much the start position of the input data 52 for match candidate search should be shifted, outputs a default value to the input control circuit 23 as the amount of shift of the start position of the input data 52 for match candidate search.

Furthermore, the header generation circuit 27 may embed, for example, a flag (end flag) indicating that recompression is not necessary, in the header of the data being compressed, instead of embedding the information capable of specifying how much the start position of the input data 52 for match candidate search should be shifted during recompression. In this case, the header analysis circuit 28 analyzes the header of the data being compressed, and when it is confirmed that recompression is not necessary for the data being compressed, ends compression processing for the data being compressed.

Furthermore, the header generation circuit 27 may further embed, in the header of the data being compressed, information indicating the data reduction rate calculated by the match selection circuit 33 in the current dictionary-based compression (i.e., dictionary-based compression performed on the data being compressed). Alternatively, the header generation circuit 27 may further embed, in the header of the data being compressed, information indicating the size of compressed data in dictionary-based compression performed before dictionary-based compression performed on the data being compressed (e.g., dictionary-based compression before last). In this case, as a result of analyzing the information embedded in the header of the data being compressed, the header analysis circuit 28 outputs a value indicating the amount of shift of the start position of the input data 52 for match candidate search to the input control circuit 23, and also outputs the value of the data reduction rate calculated when dictionary-based compression has been performed on the data being compressed and a value indicating the size of the compressed data in dictionary-based compression performed prior to the dictionary-based compression performed on the data being compressed to the match selection circuit 33. This enables the match selection circuit 33 to perform processing of step S12 shown in FIG. 6 and enables the compression device 15 to perform the series of compression processing shown in FIG. 6.

The controller 6 including the compression device 15 shown in the first, second and third embodiments executes a series of compression processing by the compression device 15 on write data received in response to, for example, reception of a write command from the host 2, and executes processing of writing the compressed data to the NAND flash memory 4. In addition, in response to, for example, reception, from the host 2, a command related to block management of the NAND flash memory 4, which is a command to move valid data in a block containing a mixture of valid data and invalid data to another block (i.e., a command to instruct execution of garbage collection), the controller 6 may read compressed data stored in the NAND flash memory 4, execute a series of compression processing (recompression) by the compression device 15 on the compressed data, and execute processing of writing the compressed data (recompressed data) to the NAND flash memory 4.

According to at least one of the embodiments described above, it is possible to provide a compression device and a memory system capable of improving the compression ratio of a dictionary-based compression circuit while suppressing an increase in the circuit size of the dictionary-based compression circuit.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A compression device that compresses input first data, comprising:
a dictionary-based compression circuit including a dictionary buffer, a match candidate search circuit, and a match selection circuit, and configured to perform dictionary-based encoding on the first data a plurality of times; and
an input control circuit configured to output input data based on the first data to the dictionary-based compression circuit,
the input control circuit is configured to:
output the first data to the match candidate search circuit from a specified start position as first input data and output the first data to the dictionary buffer from a head position as second input data having a same length as the first input data,
the dictionary buffer is configured to store, as dictionary data, data of the size of the dictionary buffer among the second input data sequentially input from the input control circuit,
the match candidate search circuit is configured to acquire the dictionary data that at least partially matches the first input data sequentially input from the input control circuit and generate compressed data through current dictionary-based encoding,
the match selection circuit is configured to:
compare, when there is compressed data corresponding to the first data generated in the past by the match candidate search circuit, the size of the compressed data generated through the current dictionary-based encoding with the size of the compressed data generated in the past and corresponding to the specified start position and output compressed data having a smaller size, and
when there is no compressed data corresponding to the first data generated in the past by the match candidate search circuit, output the compressed data generated through the current dictionary-based encoding.

2. The compression device according to claim 1, wherein the input control circuit is configured to shift a start position of the first input data by the dictionary buffer size each time recompression is performed.

3. The compression device according to claim 1, wherein the dictionary-based compression circuit is configured to determine whether or not to complete dictionary-based encoding of the first data based on the size of the compressed data generated through current dictionary-based encoding and the size of the compressed data generated in the past.

4. The compression device according to claim 1, wherein the input control circuit includes a delay buffer, and
the delay buffer is configured to output data obtained by delaying the first data by a predetermined delay amount to the dictionary buffer as the second input data.

5. The compression device according to claim 1, further comprising a dictionary-based decompression circuit configured to decompress compressed data corresponding to the first data and output the first data.

6. The compression device according to claim 5, further comprising:
an entropy encoding circuit configured to perform entropy encoding on the compressed data generated through dictionary-based encoding using the dictionary-based compression circuit to generate compressed data; and
an entropy decoding circuit configured to perform entropy decoding on the compressed data generated through entropy encoding to decode the compressed data generated through dictionary-based encoding,
wherein the match selection circuit is configured to acquire the compressed data decoded by the entropy decoding circuit as compressed data generated in the past by the match candidate search circuit and corresponding to the first data.

7. The compression device of claim 1, wherein the compressed data corresponding to the first data includes a header, and
the input control circuit is configured to identify a start position of the first input data based on the header at the time of recompression.

8. The compression device of claim 7, wherein the header includes information indicating a logical dictionary buffer size in the current dictionary-based encoding, and
the input control circuit is configured to identify a start position of the first input data based on the information included in the header at the time of recompression.

9. The compression device of claim 8, wherein the header further includes a value calculated based on the size of the compressed data generated through the current dictionary-based encoding and the size of compressed data generated in the past.

10. A memory system connectable to a host, comprising:
a non-volatile memory; and
a controller configured to control the non-volatile memory and including an interface circuit that receives an instruction from the host and a compression device that compresses first data received in response to the instruction from the host, wherein
the compression device comprises:
a dictionary-based compression circuit including a dictionary buffer, a match candidate search circuit, and a match selection circuit, and configured to perform dictionary-based encoding on the first data a plurality of times; and
an input control circuit configured to output input data based on the first data to the dictionary-based compression circuit,
the input control circuit is configured to:
output the first data to the match candidate search circuit from a specified start position as first input data and
output the first data to the dictionary buffer from a head position as second input data having a same length as the first input data,
the dictionary buffer is configured to store, as dictionary data, data of the size of the dictionary buffer among the second input data sequentially input from the input control circuit,
the match candidate search circuit is configured to acquire the dictionary data that at least partially matches the first input data sequentially input from the input control circuit and generate compressed data through current dictionary-based encoding,
the match selection circuit is configured to:
compare, when there is compressed data corresponding to the first data generated in the past by the match candidate search circuit, the size of the compressed data generated through current dictionary-based encoding with the size of the compressed data generated in the past and corresponding to the specified start position and output compressed data having a smaller size, and
when there is no compressed data corresponding to the first data generated in the past by the match candidate search circuit, output the compressed data generated through current dictionary-based encoding,
the controller writing the compressed data corresponding to the first data to the non-volatile memory.

11. The memory system according to claim 10, wherein, the controller is configured to recompress, when an instruction to move data stored in the non-volatile memory has been received from the host, the compressed data corresponding to the first data stored in the non-volatile memory by the compression device.

12. The memory system according to claim 10, wherein the input control circuit is configured to shift a start position of the first input data by the dictionary buffer size each time recompression is performed.

13. The memory system according to claim 10, wherein the dictionary-based compression circuit is configured to determine whether or not to complete dictionary-based encoding of the first data based on the size of the compressed data generated through current dictionary-based encoding and the size of the compressed data generated in the past.

14. The memory system according to claim 10, wherein the input control circuit includes a delay buffer, and
the delay buffer is configured to output data obtained by delaying the first data by a predetermined delay amount to the dictionary buffer as the second input data.

15. The memory system according to claim 10, wherein the compression device further comprises a dictionary-based decompression circuit configured to decompress compressed data corresponding to the first data and output the first data.

16. The memory system according to claim 15, wherein
the compression device further comprises:
an entropy encoding circuit configured to perform entropy encoding on the compressed data generated through dictionary-based encoding using the dictionary-based compression circuit to generate compressed data; and
an entropy decoding circuit configured to perform entropy decoding on the compressed data generated through entropy encoding to decode the compressed data generated through dictionary-based encoding,
the match selection circuit is configured to acquire the compressed data decoded by the entropy decoding circuit as compressed data generated in the past by the match candidate search circuit and corresponding to the first data.

17. The memory system of claim 10, wherein the compressed data corresponding to the first data includes a header, and
the input control circuit is configured to identify a start position of the first input data based on the header at the time of recompression.

18. The memory system of claim 17, wherein the header includes information indicating a logical dictionary buffer size in the current dictionary-based encoding, and
the input control circuit is configured to identify a start position of the first input data based on the information included in the header at the time of recompression.

19. The memory system of claim 18, wherein the header further includes a value calculated based on the size of the compressed data generated through the current dictionary-based encoding and the size of compressed data generated in the past.
